(19) United States
(12) Patent Application Publication
(10) Pub. No.: US 2026/0086318 A1
(43) Pub. Date: Mar. 26, 2026

(54) COMPONENT HAVING A HOLLOW STRUCTURE, AND OPTICAL ASSEMBLY

(71) Applicant: Carl Zeiss SMT GmbH, Oberkochen (DE)

(72) Inventors: Michael KLASNA, Stephanskirchen (DE); Thomas MONZ, Schlierbach (DE); Cristian GLEASON GONZALEZ, Stuttgart (DE); Christoph TRAXINGER, Passau (DE)

(21) Appl. No.: 19/408,046

(22) Filed: Dec. 3, 2025

Related U.S. Application Data
(63) Continuation of application No. PCT/EP2024/066102, filed on Jun. 11, 2024.

(30) Foreign Application Priority Data
Jun. 16, 2023 (DE) 102023205652.6

(51) Int. Cl. G02B 7/18; G03F 7/00

(52) U.S. Cl. CPC G02B 7/1815; G03F 7/70891

(57) ABSTRACT

A component, for example an optical element or a structural component, comprises: a main body comprising a hollow structure through which a fluid can flow and which has a plurality of cooling channels; a fluid distributor; and a fluid collector. In order to supply the fluid to the cooling channels, the fluid distributor can comprise connection channels that open into a common inlet channel connected to an inlet opening. In order to discharge the fluid from the cooling channels, the fluid collector can comprise connection channels that open into a common outlet channel connected to an outlet opening. The inlet channel can have a flow cross section that decreases starting from a connection channel adjacent to the inlet opening. The outlet channel can have a flow cross section that decreases starting from a connection channel adjacent to the outlet opening.

### REFERENCE TO RELATED APPLICATIONS

The present application is a continuation of, and claims benefit under 35 USC 120 to, international application No. PCT/EP2024/066102, filed Jun. 11, 2024, which claims benefit under 35 USC 119 of German Application No. 10 2023 205 652.6, filed Jun. 16, 2023. The entire disclosure of each of these applications is incorporated by reference herein.

### FIELD

The disclosure relates to a component, such as an optical element or a structural component, comprising: a main body comprising a hollow structure through which a fluid can flow and which has a plurality of cooling channels, a fluid distributor and a fluid collector, wherein in order to supply the fluid to the cooling channels, the fluid distributor comprises connection channels that open into a common inlet channel, which is connected to an inlet opening, and/or wherein in order to discharge the fluid from the cooling channels, the fluid collector comprises connection channels that open into a common outlet channel, which is connected to an outlet opening. The disclosure also relates to an optical arrangement, such as a lithography system, having at least one such component.

### BACKGROUND

Current lithography systems can have cooling systems with cooling circuits for the thermal stabilization of components such as optical elements or structural components. Cooling lines of the cooling circuits may be guided, in the form of hollow structures, both through the main bodies of the optical elements and through the main bodies of the structural components. In order to help attain a reasonably high heat dissipation and good controllability of the cooling system (short delay and high precision), a fluid, typically in the form of a cooling liquid, is made to flow (active cooling) through the main bodies of the cooled components, more precisely through their hollow structures. Water is frequently used as the cooling liquid as this has a high heat capacity in comparison with certain other fluids and is very readily available. The flowing fluid can also help improve heat transfer at the surfaces through which it passes (forced convection) and reduces the time constants of the thermal system in the process.

In general, there is an exchange of momentum in the flow boundary layers between the flowing fluid and the walls of the component. In the case of a laminar and stationary flow, the effect thereof is a relatively constant force on the component through which the flow passes (loss of flow pressure). If a critical flow velocity (critical Reynolds number Re; e.g. Re=2300 in pipes) that depends on the local geometric boundary conditions and on the inflow and outflow boundary conditions is exceeded, then in general small disturbances can no longer be damped by the viscosity of the flowing medium, and so a disturbance in the flow can result in sustained periodic and random fluctuations in the flow (turbulence). This turbulence typically increases the momentum transport from the flow into the main body and may in the form of flow-induced vibrations (FIV) undesirably accelerate the component, possibly even at control-critical frequencies (e.g. frequencies for controlling a mirror position), depending on the geometry, medium and flow.

Flow-induced vibrations can thus arise as a result of turbulence-induced pressure and momentum fluctuations in the fluid flow, and the resultant forces on the walls of the hollow structure or of the cooling channels can lead to a dynamic excitation of the component. Moreover, up to 10% of the hydrodynamic fluctuations (turbulence) may be output coupled into acoustic pressure waves which may also propagate upstream at the speed of sound in the cooling fluid and may be stored at resonance frequencies (like in organ pipes), depending on the geometry of the cooling circuit. Attempts have tried to minimize the creation of flow-induced vibrations by optimizing the flow guidance and having flow velocities which are as low as reasonably possible.

An issue that may arise when optimizing the flow guidance of the fluid through a hollow structure is that the hollow structure is typically produced using standard machining methods (grinding, milling, drilling, etc.). On account of manufacturing limitations, such manufacturing methods often give rise to geometries which do not have an ideal design for flows in respect of turbulence generation, acoustics and resultant force excitations. This can also affect the fluid distributor and the fluid collector.

In general, the fluid distributor and the fluid collector are arranged spatially separated from each other. The fluid distributor serves to divide the fluid flow or the fluid from the inlet opening among the plurality of cooling channels. The fluid collector serves to bring together the fluid flows from the plurality of cooling channels into the outlet opening. To this end, the fluid distributor and the fluid collector can have a plurality of branch points at which the fluid is divided among the cooling channels. It is possible that the fluid distributor and/or the fluid collector have branch points that form a tree structure. In the case of a tree structure, at least one of multiple branches formed at a first branch point can be divided again into two or more branches at a second branch point. In the case of the component described here, the fluid distributor comprises connection channels in order to connect a cooling channel or a group of cooling channels (two or more) to an inlet channel connected to an inlet opening, and/or the fluid collector comprises connection channels in order to connect a cooling channel or a group of cooling channels (two or more) to an outlet channel connected to an outlet opening.

The inlet channel and the outlet channel typically have the shape of cylindrical cavities as such cavities can easily be manufactured by milling or drilling. WO 2022/008155 A1 describes a mirror for a lithography system, the mirror comprising a fluid distributor in the form of an inlet channel and a fluid collector in the form of an outlet channel, which take the form of cylindrical bores. In that case, the connection channels referred to as distributor channels/collector channels in WO 2022/008155 A1 each open at right angles into the inlet channel or outlet channel and are likewise produced in the form of bores. The hollow structure described therein has a design that is produced by conventional manufacturing methods and not optimized with regard to the minimization of the formation of turbulence.

However, in general, only minimal flow-induced vibrations can be tolerated for example in the case of components for EUV lithography systems. The maximum permissible forces generated by flow-induced vibrations typically are in the order of mN to μN in that case.

### SUMMARY

The disclosure seeks to provide a component and an optical arrangement having at least one such component, in which the generation of flow-induced vibrations is reduced.

According to a first aspect, the disclosure provides an inlet channel having a flow cross section that decreases (in a longitudinal direction of the inlet channel) starting from a connection channel adjacent to the inlet opening, and/or an outlet channel having a flow cross section that decreases (in a longitudinal direction of the outlet channel) starting from a connection channel adjacent to the outlet opening.

For the sake of simplicity, the assumption is made below that the hollow structure is symmetrical with respect to the fluid distributor and the fluid collector, i.e. the fluid distributor and the fluid collector have an identical geometry. Accordingly, only the fluid collector or the inlet channel is described below, and the assumption is made that statements made in relation to the fluid distributor also apply accordingly to the fluid collector. However, this is not necessarily the case, i.e., in general, the fluid distributor and the fluid collector may have different geometries which are optimized for the respective flow conditions (e.g. flow direction, swirl, widening/tapering, etc.). Different geometries may be favorable since the flow conditions in the fluid distributor and in the fluid collector differ considerably on account of their different functionalities. The fluid distributor serves to distribute the fluid among the cooling channels, and this process should be as uniform as possible and with as little turbulence as possible. The fluid collector serves to collect the fluid. As a result of the fluid flowing from the cooling channels, which typically have a relatively small diameter, into the connection channels, which are generally at right angles to the cooling channels, and from a respective connection channel into the outlet channel of the fluid collector, turbulent flows—FIV—afflicted flows—may arise due to jumps in the diameter and on account of shearing. This fact may possibly result in different design solutions for the fluid collector compared to the fluid distributor.

The inventors have recognized that an inlet channel with a cylindrical geometry is unfavorable with regard to the generation of turbulence or flow-induced vibrations in the fluid collector. On account of the fact that multiple connection channels, which each receive a portion of the volume flow, successively branch off the inlet channel in the longitudinal direction of the inlet channel, the volume flow in the inlet channel decreases in the longitudinal direction of the inlet channel starting from the connection channel adjacent to the inlet opening. The decreasing volume flow may lead to flow separation in the inlet channel and hence to turbulent and/or periodic fluctuation movements (exponential gradient of the flow velocity in the inlet channel). Turbulent flows may also form in the connection channels that open into the inlet channel.

It is proposed to adapt the flow cross section in the inlet channel (or in the outlet channel) to the decrease in velocity (and pressure gradient) in order to reduce the generation of turbulence. It is not mandatory for the flow cross section to decrease strictly monotonically over the entire length of the inlet channel or of the outlet channel. Within the meaning of this application, the decrease in the flow cross section is understood to mean that the inlet channel (or the outlet channel) may also have sections with a constant flow cross section. However, overall, the flow cross section of the inlet channel or of the outlet channel decreases to the end of the inlet channel (or of the outlet channel) starting from the connection channel adjacent to the inlet opening or the outlet opening.

The decrease in the flow cross section may be realized in different ways from a manufacturing point of view. Conventional manufacturing methods, for example milling or drilling, may be used to realize the decrease in the flow cross section. However, it is also possible to realize an inlet channel with a decreasing flow cross section with the aid of novel, alternative manufacturing methods that are not standard mechanical machining methods (grinding, milling, drilling, etc.) in which the geometry of the hollow structure that can be produced from a manufacturing point of view is very limited (see above). In general, alternative manufacturing methods may allow the generation of a hollow structure with virtually any desired, optionally complex geometry in the main body. Thus, hollow structures optimized with regard to the fluid flow and to flow-induced vibrations may be realized with the aid of alternative manufacturing methods. For example, the alternative manufacturing method may be selective laser etching or rear-side laser ablation.

In selective laser etching, light in the form of ultrashort pulsed laser radiation (ps or fs pulses) is focused in the volume of a transparent workpiece or main body. In this case, the pulse energy is only absorbed within the focus volume as a result of multi-photon processes. In the focus volume, the optical and chemical properties of the transparent material are changed, without cracks or possibly with microcracks, in such a way that it is rendered selectively chemically etchable. By moving the focus volume in the material, contiguous volume regions are modified, and these can subsequently be removed via wet chemical etching. In the case of wet chemical etching, the main body is typically immersed in an etching solution over several weeks or months, the etching solution can (selectively) remove the modified material. As a result of the movement of the focus volume within the workpiece, hollow structures of any desired geometry may in principle be produced with the aid of the selective laser etching, for example as described in WO2021115643 A1.

In rear-side laser ablation, light in the form of ultrashort pulsed laser radiation (ps or fs pulses) is likewise focused in the volume of a transparent workpiece or main body. In contrast to selective laser etching, the material of the main body is removed directly by way of correspondingly high pulse energies in order to produce the hollow structure. As in selective laser etching, rear-side laser ablation makes use of the fact that materials in the form of conventional glasses such as silica glass, borosilicate glass or else titanium-doped quartz glass (ULE®) are transparent to laser radiation with wavelengths in the visible (VIS) to near infrared range. Generally, energy can only be deposited in the material by multi-photon absorption once the intensity of the laser pulses is high enough. As a result, the laser pulses can be focused on the rear side of the material virtually without losses or distortion, and so the laser pulses are absorbed, and material removal can take place only in the near-focus region of the rear side.

Methods for removing material by laser ablation starting from the rear side of a workpiece or main body are described e.g. in the article “Three-dimensional hole drilling of silica glass from the rear surface with femtosecond laser pulses”, Y. Li et al., Optics Letters Vol. 26(23), pages 1912-1914 (2001), in the article “Precision glass machining, drilling and profile cutting by short pulse lasers”, S. Nikumb et al., Thin Solid Films, Vol. 477(1-2), pages 216-221 (2005) or in the article “Water-assisted femtosecond laser ablation for fabricating three-dimensional microfluidic chips”, Yan Li, Shiliang Qu, Current Applied Physics, Vol. 13, Issue 7, 2013, pages 1292-1295.

Depending on the production method used, the decrease in flow cross section may be implemented in steps (optionally in the case of conventional manufacturing methods) or continuously, which may be achieved by alternative manufacturing methods or optionally likewise by conventional manufacturing methods.

In an embodiment, the flow cross section of the inlet channel can decrease linearly in the longitudinal direction of the inlet channel, and/or the flow cross section of the outlet channel can decrease linearly in the longitudinal direction of the outlet channel. In order to approximate a substantially constant decrease in the flow velocity of the fluid in the longitudinal direction of the inlet channel on account of the connection channels that open into the inlet channel, it is typically favorable for the flow cross section of the inlet channel to decrease linearly in the longitudinal direction starting from the inlet opening. Such a linear decrease is typically favorable on account of the stepwise reduction in the volume flow at the respective distributor channels, where a respective proportion of the volume flow is branched off from the inlet channel.

A linear decrease in the flow cross section in the longitudinal direction of the inlet channel is understood to mean that for a plurality of positions yᵢ in the longitudinal direction y of the inlet channel, which at least correspond to the number of connection channels, the associated flow cross section Aᵢ(yᵢ) satisfies the equation of a straight line, i.e. the following applies:

$${A}_{i} ( {y}_{i} ) = {A}_{0} - const . {y}_{i} .$$

The linear decrease in the flow cross section in the longitudinal direction of the inlet channel may be continuous or stepwise (see below). The inlet channel does not have any discontinuities in the flow cross section in the first case. In this case, the equation above may be satisfied for all positions in the longitudinal direction of the inlet channel. However, it is also possible for the equation above to be satisfied only for a plurality of positions, which for example but not necessarily correspond to the number of connection channels, where a respective position yᵢ is assigned to one of the connection channels. Between these positions yᵢ, the flow cross section in this case deviates (slightly) from the equation above. Within the meaning of this application, the longitudinal direction of the inlet channel is understood to mean a line along which the connection channels open into the inlet channel at the circumferential wall of the inlet channel. Thus, the longitudinal direction is not the direction on which the centers of the flow cross sections of the inlet channel are located.

Alternatively, it is possible for the flow cross section to decrease linearly in multiple steps, with one step typically being assigned to the opening of a respective connection channel. As a result of the stepwise reduction in the flow cross section, a linear decrease of the flow cross section in the longitudinal direction of the inlet channel can be realized approximately (at the respective steps). The positions yᵢ at which the equation above is satisfied in this case typically correspond to the locations at which a respective step is located.

In an embodiment, the inlet channel and/or the outlet channel has/have a flow cross section which is of circular form. For the case described above where the flow cross section decreases linearly starting from the inlet opening/outlet opening, the decrease in flow cross section A can be described directly by way of its radius R, i.e. the flow cross section A is proportional to R², i.e. A˜R² applies. Accordingly, a profile in the form of parabolic curve (or root curve) arises for the local radius R in the longitudinal direction of the inlet channel. As described above, there may be a linear or stepwise decrease in the flow cross section. For example, the root profile can only be assumed at specific nodes or at a plurality of positions in the longitudinal direction of the inlet channel, and the root profile can be approximated by linearly interpolated sections between these positions. Simulations have shown that use of the above-described circular inlet channel with a linearly decreasing flow cross section renders a reduction in the FIV of between 30%-90% possible in comparison with an inlet channel with a circular flow cross section and a constant radius R. The linear decrease in the flow cross section thus can help enable a significant reduction in flow-induced vibrations. A further reduction in the flow-induced vibrations can be achieved by an iterative optimization of the profile of the flow cross section, which uses the linear decrease in the flow cross section described here as an initial configuration.

In an embodiment, the inlet channel and/or the outlet channel have a rectangular flow cross section or a rectangular cross-sectional portion, optionally with a width of the rectangular flow cross section or rectangular cross-sectional portion being constant and a height of the rectangular flow cross section or rectangular cross-sectional portion decreasing, for example decreasing linearly.

The longitudinal directions of the connection channels typically run in a common plane, in which the longitudinal direction of the inlet channel also runs. The width of the rectangular flow cross section or cross-sectional portion is measured perpendicular to this plane, and the height of the cross section is measured in this plane. The constant width of the flow cross section or cross-sectional portion ensures that there is no jump in diameter at the transition between the inlet channel and a respective connection channel, as would be the case if the width of the flow cross section or cross-sectional portion were to also decrease. In the case of a constant width b of the flow cross section, a particularly simple relationship between the flow cross section A (or its area) and the height h of the flow cross section in the form of a linear function between area A and heigh h arises for the constant (linear) decrease of the flow cross section, i.e. the following applies: A˜h (at least at the above-described plurality of positions in the longitudinal direction of the inlet channel or of the outlet channel).

In general, the flow cross section of the inlet channel or outlet channel may have any desired geometry. For example, the flow cross section may be composed of two or more cross-sectional portions that have a predetermined geometry. Such a cross-sectional portion may have e.g. the above-described rectangular geometry.

In a development of the above embodiment, the inlet channel and/or the outlet channel have a flow cross section that is composed of a rectangular cross-sectional portion and a semicircular cross-sectional portion. The semicircular cross-sectional portion typically adjoins the side of the rectangular cross-sectional portion with the constant width. In this case, the diameter of the semicircular cross-sectional portion corresponds to the width of the rectangular cross-sectional portion. This can help ensure that the width of the flow cross section remains constant over the length of the inlet channel or outlet channel, and there is no jump in diameter at the transition into the connection channels. The flow cross section described here is desirable from a manufacturing point of view and may be realized by e.g. a combination of milling and drilling.

In an embodiment, the inlet channel and/or the outlet channel have a flow cross section which is of ring-shaped form. The ring-shaped flow cross section forms a ring-shaped gap, with the outer circumference of the ring-shaped flow cross section typically being constant and the inner circumference increasing starting from the connection channel adjacent to the entrance opening or the exit opening in order to realize the decreasing flow cross section. The ring-shaped flow cross section may be a round flow cross section with an outer radius and an inner radius. However, the ring-shaped flow cross section may also be a rectangular ring or a free-form cross section, provided that the decrease in cross section can be realized in a manner suitable for manufacturing purposes. In this case, too, it is possible to realize a linear decrease in the flow cross section in the longitudinal direction of the inlet channel or of the outlet channel by virtue of suitably choosing the ratio of outer radius to inner radius or of outer circumference to inner circumference. The ring-shaped flow cross section is moreover desirable in that a further boundary layer forms within the flow on the inner side of the ring-shaped gap, and this has a stabilizing effect on the flow and reduces the tendency of the flow to separate.

The ring-shaped flow cross section may be realized by virtue of removing material from the main body in a ring-shaped manner. However, it is also possible for the ring-shaped flow cross section to be formed by virtue of introducing an additional component into an e.g. cylindrical inlet channel, with the additional component being formed in the manner of a rod with a conical geometry, the cross section of which increases with increasing distance from the inlet opening or from the outlet opening through which the rod is introduced into the main body. This additional component is secured in the inlet channel, for example by virtue of the additional component being attached to a fluid line or to an adapter of a fluid line connected to the entrance opening.

In an embodiment, an opening cross section of a respective connection channel of the fluid distributor decreases starting from the connection channel adjacent to the inlet opening and/or an opening cross section of a respective connection channel of the fluid collector decreases starting from the connection channel adjacent to the outlet opening. This embodiment can be favorable especially in combination with the above-described embodiment in which the diameter of the flow cross section decreases starting from the connection channel adjacent to the inlet opening or the outlet opening because this case may lead to a significant jump in cross section at the transition between the inlet channel or the outlet channel and the respective connection channels, especially if these are far away from the inlet opening or from the outlet opening. In order to help avoid the jump in cross section and flow-induced vibrations accompanying this, the opening cross section of a respective connection channel, more precisely the opening diameter thereof, can be adapted to the local diameter of the flow cross section of the inlet channel or of the outlet channel at the position in the longitudinal direction at which the connection channel opens. To reduce FIV, it is favorable, especially in this case, if the flow cross section of a respective cooling channel decreases with increasing distance from the cooling channels (see below).

In an embodiment, the connection channels have a flow cross section that decreases with increasing distance from the cooling channels. This embodiment is favorable especially in combination with the above-described embodiment in which the opening cross section of the connection channels varies. In this case for example, it was found to be favorable for the flow cross section of the connection channels to not be constant but adapted to the respective opening cross section.

In a development of this embodiment, the connection channels are of conical form, optionally with an opening angle of the conical connection channels being less than 8°. In this case, the connection channels generally have a circular cross section. The choice of opening or flank angle depends on the local flow velocity or on the local flow profile. If identical flow cross sections of the connection channels at the transition to the cooling channels are assumed, then the opening angle of the connection channels increases with increasing distance from the inlet opening or from the outlet opening in the above-described embodiment in which the opening cross section of the connection channels decreases with increasing distance from the inlet opening or from the outlet opening.

In an embodiment, the flow cross section of the inlet channel and/or of the outlet channel decreases in steps. As described above, a linear or constant cross-sectional decrease can be approximated even in the case of a stepwise decrease in the flow cross section. The greater the number of steps, the generally smaller the change in the flow cross section at the respective step. Changes in the flow cross section that are too large (>5% in relation to the respective larger flow cross section at the step) should be avoided in order to prevent local flow separations. As described above, the respective flow cross section that decreases in stepwise fashion may for example be of circular or rectangular form or of a form that is a combination of the two or of ring-shaped form. The stepwise decrease in the flow cross section can help enable or facilitate the manufacture with the aid of conventional production methods, albeit with greater outlay.

It is also possible to adapt the flow cross section of the inlet channel or of the outlet channel individually to the respective flow conditions or boundary conditions in a manner other than that described above. As described above, it is not mandatory for the flow cross section of the inlet channel and of the outlet channel and of the connection channels to be of circular form. In this case, all types of cascading (stepwise change) or diameter design which do not result in a flow cross section that is constant over its length may be considered here.

A second aspect of the disclosure relates to a component, wherein the inlet channel has a constant flow cross section and/or wherein the outlet channel has a constant flow cross section, and wherein at least two of the connection channels have a different flow cross section in each case. In order to counteract the flow separation in the inlet channel or in the outlet channel on account of the pressure gradient and the volume flow decrease (see above), the volume flow discharge from the inlet channel or into the outlet channel may also be controlled by way of the connection channels. In this case, the counterpressure or the volume flow discharge may be influenced by way of the flow cross section in the connection channels. In this case, too, the objective is to design the pressure gradient in the inlet channel or in the outlet channel to be as constant as is reasonably possible. Since this generally depends not only on the static pressure distribution (volume flow distribution) but also on the dynamic properties of the flow, it is generally not possible to specify a unique geometric or analytical relationship in the form of a calculation rule in the aspect of the disclosure described here. Rather, in general, a suitable relationship in this case is to be found by way of an iterative approximation (for example by a simulation).

What applies in general is that interactions within the flow between the inlet channel or the outlet channel and the distributor channels may arise in the second aspect of the disclosure. Attention is drawn to the fact that smaller cross sections potentially lead to higher flow velocities. This may result in an increase in both turbulence and the tendency to separate at sharp edges and transitions. This interaction is to be considered holistically in order to be able to evaluate the desired positive effect. In the above-described first aspect of the disclosure, too, it is possible for at least two of the connection channels to have a different flow cross section in each case, i.e. it is not mandatory, i.e. the flow cross section of the connection channels may also vary if the flow cross section of the inlet channel and of the outlet channel decreases.

In an embodiment, which may be combined with the above-described first aspect or with the second aspect of the disclosure, a flow cross section of the connection channels increases starting from a connection channel adjacent to the inlet opening or starting from a connection channel adjacent to the outlet opening. Increase in the flow cross section is understood to mean that the flow cross section of the connection channels increases over the length of the inlet channel or over the entire length of the outlet channel. A connection channel at a further distance from the inlet opening than an adjacent connection channel typically has at least the same flow cross section as the adjacent connection channel. The connection channel furthest away from the inlet opening/outlet opening has the largest flow cross section. As a result of the increase in the flow cross sections of the connection channels, it is possible to achieve a similar effect to the decrease in the flow cross section of the inlet channel or of the outlet channel starting from the inlet opening or from the outlet opening. The two measures may be combined with each other, but this is not mandatory. Below, the assumption is made that the flow cross section of a respective connection channel is constant. Should this not be the case, the flow cross section is generally understood to mean the cross section averaged over the length of the connection channel.

In an embodiment, the flow cross sections of at least two adjacent connection channels, optionally of at least three adjacent connection channels, are of the same size. It is possible to divide the connection channels into groups of adjacent connection channels with the same flow cross sections. For example, such a group may contain two, three or four connection channels. It was found that, given a suitable design, this can help enable a reduction in FIV in the order of approx. 10%-50%. The configuration described herein may optionally also form the starting point for simulations in order to further optimize the flow guidance. It is also possible to individually predetermine the flow cross section of a respective connection channel or of all connection channels. For example, every connection channel may have a different flow cross section. To be considered here are the resultant geometric pressure loss and dynamic (local) pressure loss in the respective connection channel, which are involved in determining the pressure gradient in the inlet channel or in the outlet channel.

In an embodiment, at least one connection channel has a conical section at the transition to the cooling channels. It is desirable for the conical section to help enable flow guidance at the transition to the cooling channels which does not involve jumps in the cross section. For example, this may be favorable if a respective connection channel serves to supply the fluid to two or more cooling channels, for example as described in WO 2022/008155 A1 cited at the outset, the entirety of which is incorporated in the content of this application by reference. To this end, WO 2022/008155 A1 proposes the use of a stepped bore with a larger bore diameter at the transition to the cooling channels. In place of the section with the larger bore diameter, the conical section can be used in the present application in order to avoid a corresponding jump in cross section.

It is not mandatory for all connection channels to have a conical section. Rather, the number, dimensioning and position of the conical sections may vary in order to prevent the separation of the flow. The conical sections are not taken into account when determining the above-described flow cross section of the connection channels. As regards the opening angle of the conical sections, the same dimensioning rules apply as to the above-described conical connection channels (opening angle <8°).

Starting from an ideal but not mandatory symmetrical basic geometry, wherein the global pressure loss is decisively dominated by the cooling channels and hence the cooling medium can be assumed to be approximately uniformly distributed among the at least two cooling channels for parallel structures, the above-described changes in the flow cross section of the inlet channel or of the outlet channel and/or of the connection channels typically play a subordinate role for the pressure loss and hence for the volume flow through a respective cooling channel since the majority of the pressure loss in the fluid arises as it flows through the cooling channels themselves. This is attributable to the fact that the cooling channels have a small flow cross section in comparison with the connection channels and the inlet channel or the outlet channel, and the pressure loss generally depends on the fourth power of the flow diameter and linearly on the flow length. Accordingly, there is an approximately equal distribution of the volume flow among all of the cooling channels (provided that these themselves have an identical geometry) despite the above-described change in the flow cross section of the inlet channel or of the outlet channel and/or of the distributor channels.

In an aspect of the disclosure, which may for example be combined with the first or the second aspect, a longitudinal direction of the connection channels and a longitudinal direction of the inlet channel and/or of the outlet channel are oriented at an acute outflow angle to each other, the latter optionally being less than 70°.

As described above, there are generally limitations with respect to the design of the fluid distributor and of the fluid collector when using conventional manufacturing methods. The connection channels and the inlet channel or the outlet channel are typically perpendicular to one another in order to divert the flow into a plane parallel to the cooling channels. This results in sharp edges and limited angular ranges where flow separations generally occur, and these increase the FIV excitation or the FIV contribution. In order to avoid these sharp edges, it is possible to round them off or attempt to allow the channels to extend at tangential radii with respect to one another. For the reduction of flow-induced vibrations, it can be simpler if the outflow angle between the longitudinal direction of the connection channels and the longitudinal direction of the inlet channel or of the outlet channel is reduced. In general, the smaller or flatter the outflow angle, the smaller the flow-induced vibrations typically are. In general, it is generally desirable for the acute outflow angle to be chosen to be <90° in all cases and to be reduced as much as reasonably possible, close to the optimum of 0°. In this way, it can be possible to reduce flow separation, especially in the connection channels. The aspect described here can be realized both on the fluid distributor and on the fluid collector.

In an aspect of the disclosure, which may be combined with the above-described aspects, a distance between the inlet channel and the cooling channels decreases starting from the connection channel adjacent to the inlet opening and/or a distance between the outlet channel and the cooling channels decreases starting from the cooling channel adjacent to the outlet opening. As a result of the oblique alignment of the inlet channel or of the outlet channel with respect to the cooling channels, it is possible to reduce the outflow angle between the longitudinal direction of the connection channels and the longitudinal direction of the inlet channel or of the outlet channel. If both the inlet channel or the outlet channel and the connection channels are aligned at an angle to a surface of the main body below which the cooling channels run, it is possible—depending on the dimensioning of the main body—to generate the smallest reasonably possible outflow angle. In general, as regards the reduction of the outflow angle, it can be unimportant whether the connection channels alone, the inlet channel/outlet channel alone or both channel types at the same time are inclined with respect to the surface or the cooling channels. Further optimization can be brought about by rounding off all edges in the flow direction.

In an embodiment, the main body has a first partial body and a second partial body that are rigidly connected to each other along a joining surface, with the hollow structure being formed in at least one of the partial bodies. If the component is an optical element in the form of a mirror, the main body (mirror substrate) is typically initially produced as a whole in this embodiment, and the two or more partial bodies are formed therefrom by mechanical processing. Material is removed from at least one of the partial bodies in order to form the hollow structure or a part of the hollow structure. The two partial bodies are subsequently rigidly connected to each other along the joining surface. To establish the connection, it is possible to use a bonding method which allows the connection to be established without the use of a joining mechanism, for example what is known as fusion bonding. The joining surface may be a planar surface, but it is also possible for the joining surface to be a curved surface. The substrate may be a material with a coefficient of thermal expansion that is as low as possible, for example a glass ceramic, e.g. Zerodur®.

Joining together of two or more partial bodies in order to form the main body may be desirable in the above-described standard manufacturing methods for example, in order to realize complex geometries of the hollow structure. The joining surface typically extends perpendicular or substantially perpendicular to a (vertical) plane in which the connection channels typically run. This can help facilitate the manufacture of the hollow structure by drilling, milling and/or grinding in order to realize (possibly approximately) the above-described designs. It is understood that the main body may alternatively also be formed in one piece, especially if the above-described alternative manufacturing methods are used.

If the component is an optical element for reflecting radiation, in the form of a mirror, the cooling channels generally run substantially parallel to the reflective surface of the mirror at a comparatively small distance from the reflective surface. At least one section of the fluid distributor and of the fluid collector adjacent to the cooling channels is typically aligned substantially perpendicular to the cooling channels, i.e. at an angle between 80° and 100°, for example at an angle of approx. 90°, in order to remove the fluid as quickly as reasonably possible from the reflective surface.

An aspect of the disclosure relates to an optical arrangement, for example a lithography system, comprising: at least one component designed as described above, for example an optical element or a structural component, and a cooling device that is designed to allow a cooling fluid to flow through the hollow structure of the main body. The lithography system may be a lithography apparatus for exposing a wafer, for example an EUV lithography apparatus that uses radiation at an operating wavelength in the EUV wavelength range. Alternatively, it may also be a different optical arrangement for (EUV) lithography, for example an EUV inspection system, e.g. for inspecting masks, wafers or the like used in EUV lithography. The optical element may be a mirror of a projection system of an EUV lithography apparatus.

For example, the cooling device may be designed to allow a cooling fluid, typically a cooling liquid, e.g. in the form of cooling water or the like, to flow through the cooling channels. For this purpose, the cooling device may optionally have a pump and also suitable feed and discharge lines. The optical arrangement may also be a lithography system for another wavelength range, e.g. for the DUV wavelength range, for example a DUV lithography apparatus or an inspection system for inspecting masks, wafers, optical (mirror) elements or the like.

As described above, the component whose main body comprises the hollow structure need not necessarily be an optical element; rather, it may also be a different type of component. For example, the component may be a structural component, e.g. in the form of a mount, for example in the form of a frame for mounting optical elements, a frame for mounting sensors, or in the form of a force frame, such as are used in EUV lithography systems, specifically in EUV lithography apparatuses. In the case of such structural components, the main body is frequently formed from materials such as aluminum, steel, ceramics, e.g. SiSiC, etc. The optical arrangement described above may comprise at least one structural component for example, the main body of which comprises a hollow structure through which a cooling fluid flows via the cooling device.

Further features and aspects of the disclosure will be apparent from the description of exemplary embodiments of the disclosure that follows, with reference to the figures of the drawing, which show certain details of the disclosure, and from the claims. In a variant of the disclosure, the individual features may each be implemented individually or several features may be implemented together in any combination.

### BRIEF DESCRIPTION OF THE DRAWINGS

Exemplary embodiments are illustrated in the schematic drawings and are elucidated in the description that follows. In the drawings:

FIG. 1 shows a schematic meridional section through a projection exposure apparatus for EUV projection lithography;

FIG. 2 shows a schematic illustration of a main body of a mirror from the projection exposure apparatus in FIG. 1, having a hollow structure comprising cooling channels, a fluid collector and a fluid distributor;

FIG. 3 shows a schematic sectional illustration of the fluid distributor in the hollow structure from FIG. 2 with an illustration of the turbulent kinetic energy when a fluid flows through the fluid distributor;

FIG. 4A shows an illustration analogous to FIG. 3, wherein the fluid distributor comprises an inlet channel with a circular flow cross section that decreases in the longitudinal direction of the inlet channel;

FIG. 4B shows an illustration analogous to FIG. 4A, wherein the fluid distributor has conical connection channels;

FIG. 5 shows an illustration of the relationship between the local diameter of the inlet channel and the maximum diameter of the inlet channel when the flow cross section decreases linearly in the longitudinal direction of the inlet channel;

FIG. 6 shows an illustration analogous to FIGS. 4A-4B with an inlet channel that comprises a rectangular flow cross section with decreasing height;

FIGS. 7A-7B show illustrations of a rectangular flow cross section and a flow cross section comprising a rectangular and a semicircular cross-sectional portion;

FIG. 8 shows an illustration analogous to FIG. 6, wherein the flow cross section of the inlet channel decreases in stepwise fashion;

FIGS. 9A-9B show illustrations analogous to FIG. 3 or to FIGS. 7A-7B, wherein the inlet channel has a ring-shaped flow cross section;

FIG. 10 shows an illustration analogous to FIG. 3, wherein the inlet channel has a constant flow cross section and wherein a flow cross section of the connection channels increases with increasing distance from the inlet opening;

FIG. 11 shows an illustration analogous to FIG. 3, wherein the inlet channel has a constant flow cross section and is aligned at an acute outflow angle with respect to the connection channels; and

FIG. 12 shows an illustration analogous to FIG. 11, wherein the inlet channel has a decreasing flow cross section starting from the inlet opening and wherein the connection channels have an increasing flow cross section starting from the inlet opening.

### DETAILED DESCRIPTION

In the description of the drawings that follows, identical reference signs are used for identical or functionally identical components.

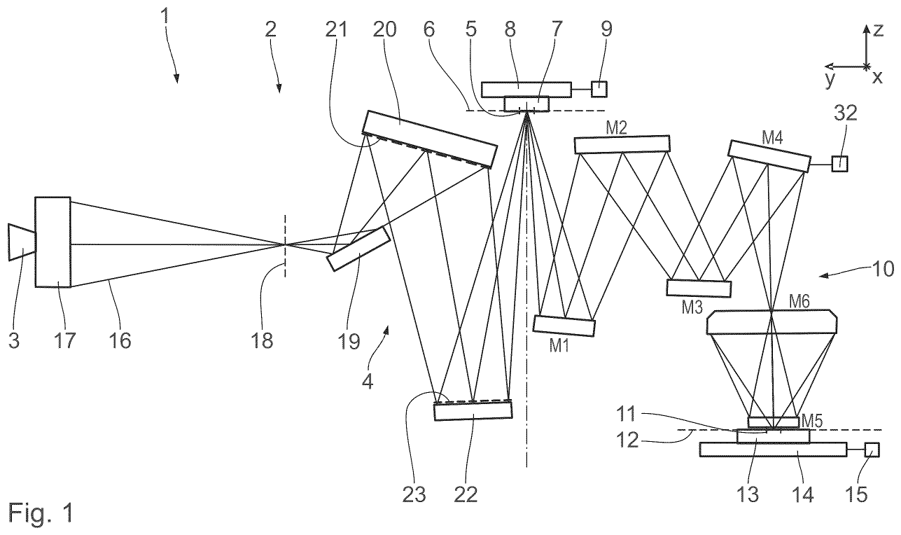

Certain constituent parts of an optical arrangement for EUV lithography in the form of a microlithographic projection exposure apparatus 1 are described by way of example below with reference to FIG. 1. The description of the basic setup of the projection exposure apparatus 1 and the constituent parts thereof should not be understood to have a limiting effect.

An embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9 for example in a scanning direction.

For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15 for example in the y-direction. The displacement of the reticle 7 on the one hand by way of the reticle displacement drive 9 and of the wafer 13 on the other hand by way of the wafer displacement drive 15 may be synchronized.

The radiation source 3 is an EUV radiation source. The radiation source 3 emits for example EUV radiation 16, which is also referred to below as used radiation, illumination radiation or illumination light. The used radiation has for example a wavelength in the range between 5 nm and 30 nm. The radiation source 3 may be a plasma source, for example an LPP (Laser Produced Plasma) source or a GDPP (Gas Discharge Produced Plasma) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

Downstream of the collector mirror 17, the illumination radiation 16 propagates through an intermediate focus in an intermediate focal plane 18. The intermediate focal plane 18 may constitute a separation between a radiation source module, comprising the radiation source 3 and the collector mirror 17, and the illumination optics unit 4.

The illumination optics unit 4 comprises a deflection mirror 19 and, disposed downstream thereof in the beam path, a first facet mirror 20. The deflection mirror 19 may be a plane deflection mirror or, alternatively, a mirror with a beam-influencing effect that goes beyond the pure deflection effect. In an alternative to that or in addition, the deflection mirror 19 may take the form of a spectral filter that separates a used light wavelength of the illumination radiation 16 from extraneous light of a wavelength differing therefrom. The first facet mirror 20 comprises a multiplicity of individual first facets 21, which are also referred to below as field facets. Only some of these facets 21 are shown in FIG. 1 by way of example. In the beam path of the illumination optics unit 4, a second facet mirror 22 is disposed downstream of the first facet mirror 20. The second facet mirror 22 comprises a plurality of second facets 23.

The illumination optics unit 4 thus forms a doubly faceted system. This basic principle is also referred to as a fly's eye integrator. The second facet mirror 22 is used to image the individual first facets 21 into the object field 5. The second facet mirror 22 is the last beam-shaping mirror or else actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve, or any other number of mirrors Mi are similarly possible. The penultimate mirror M5 and the last mirror M6 each have a passage opening for the illumination radiation 16. The projection system 10 is a doubly obscured optics unit. The projection optics unit 10 has an image-side numerical aperture which is greater than 0.4 or 0.5 and which may also be greater than 0.6 and which may be for example 0.7 or 0.75.

Just like the mirrors of the illumination optics unit 4, the mirrors Mi may have a highly reflective coating for the illumination radiation 16.

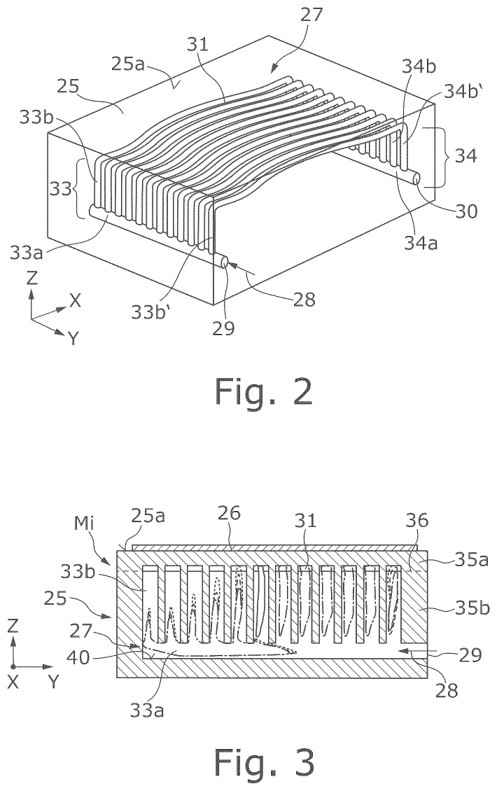

FIG. 2 shows, by way of example, a main body in the form of a substrate 25 for one of the mirrors Mi of the projection system from FIG. 1. In the example shown, the material of the substrate 25 is ultra-low expansion glass (ULE®). The substrate 25 may also be formed from a different material having a coefficient of thermal expansion that is as small as possible, for example from a glass ceramic, e.g. Zerodur®.

A reflective face in the form of a reflective coating 26 (cf. FIG. 3) is applied to a surface 25a of the substrate 25. A portion of the surface 25a located within the reflective coating 26 is struck by the EUV radiation 16 of the projection system 10 and forms an optically used portion of the reflective coating 26 (not depicted here). To reflect the EUV radiation 16, the reflective coating 26 may have, for example, a plurality of layer pairs made of materials with in each case a different real part of the refractive index, the layer pairs possibly being formed from Si and Mo, for example, in the case of a wavelength of the EUV radiation 16 of 13.5 nm.

The substrate 25 comprises a hollow structure 27 through which a fluid 28 can flow, the latter being cooling water in the example shown. The fluid 28 indicated by an arrow in FIG. 2 enters into the substrate 25 via an inlet opening 29 on a side surface in order to flow through a plurality of cooling channels 31, which form a part of the hollow structure 27, in order thus to cool for example the surface 25a of the substrate 25 to which the reflective coating 26 has been applied.

To supply the fluid 28 to the inlet opening 29 and to remove the fluid 28 from an outlet opening 30 of the substrate 25, the projection exposure apparatus 1 comprises a temperature control device in the form of a cooling device 32, which is depicted very schematically in FIG. 1. In the example shown, the cooling device 32 serves to supply the fluid 28 in the form of cooling water to the hollow structure 27 or to the fourth mirror M4, and to this end comprises a supply line, not depicted here, which is connected to the inlet opening 29 in fluid-tight fashion. The cooling device 32 also comprises a discharge line (not depicted here) for removing the cooling water via the outlet opening 30 of the substrate 25 or from the hollow structure 27. The other mirrors M1-M3, M5, M6 of the projection system 10 and the mirrors of the illumination system 2 may also, for cooling purposes, be connected to the cooling device 32 or optionally to further temperature control or cooling devices provided to this end.

As evident from FIG. 2, the fluid 28 enters a cylindrical inlet channel 33a, which is part of the hollow structure 27 and forms a part of a fluid distributor 33, via the inlet opening 29. A plurality of (first) connection channels 33b branch off the inlet channel 33a and are each connected to one of the plurality of cooling channels 31. The cooling channels 31 are arranged at a constant distance of less than approx. 10 mm from the surface 25a of the substrate 25, which is convexly curved in the example shown. The surface 25a has convex curvature along sectional planes XZ which extend perpendicular to the Y-direction of an XYZ-coordinate system. By contrast, the surface 25a is planar along sectional planes YZ which extend perpendicular to the X-direction. The cooling channels 31 run substantially in a straight line in their longitudinal direction, which corresponds to the X-direction, and extend in the longitudinal direction over approximately the entire portion of the surface 25a of the substrate 25 covered by the coating 26. From the cooling channels 31, the fluid 28 flows through a plurality of (second) connection channels 34b to a cylindrical outlet channel 34a of a fluid collector 34. The fluid 28 emerges from the hollow structure 27 of the substrate 25 via the outlet opening 30 at the end face of the cylindrical outlet channel 34a.

As evident from FIG. 2, the cooling channels 31 initially run in the horizontal direction (X-direction) starting from the first connection channels 33b or second connection channels 34b, while the (first and second) connection channels 33b, 34b run in the vertical direction (Z-direction). Accordingly, the longitudinal axes of the cooling channels 31 at the transition to a respective connection channel 33b, 34b are aligned at an angle of 90° with respect to the longitudinal axes of the connection channels 33b, 34b. Such an alignment at an angle of approx. 90° is typical for the production of the hollow structure 27 in the substrate 25 by a standard processing method, which will be described in more detail below.

To produce the hollow structure 27, the substrate 25 shown in FIG. 2 is split into two partial bodies 35a, 35b, which are indicated in FIG. 3. The first, upper partial body 35a is substantially planar. The reflective face in the form of the coating 26 is applied to the first partial body 35a. The second, substantially larger partial body 35b is connected to the first partial body 35a at a common joining surface 36. It is possible to connect the two partial bodies 35a, 35b along the joining surface 36 by way of a bonding method, for example by way of fusion bonding. In the example shown, the first partial body 35a and the second partial body 35b are formed from the same material (ULE®; see above), but it is also possible for the first partial body 35a and the second partial body 35b to be formed from different materials.

The cooling channels 31 are formed during the production of the hollow structure 27 by virtue of material being removed from the first partial body 35a, i.e. the cooling channels 31 extend into the first partial body 35a starting from the joining surface 36. The fluid distributor 33 and the fluid collector 34 are formed in the second partial body 35b by virtue of material being removed from the second partial body 35b, i.e. the fluid distributor 33 and the fluid collector 34 extend into the second partial body 35b starting from the joining surface 36. In the case of the hollow structure 27 illustrated in FIG. 2, the material is removed by a standard manufacturing method, more precisely by milling or by drilling.

A turbulence field of the liquid 28 flowing through the fluid distributor 33 is illustrated in the illustration of FIG. 3, with the contours bounded by dotted or dash-dotted lines representing volume regions with high turbulence or with high turbulent kinetic energy. As evident from FIG. 3, volume regions with high turbulence occur both in the inlet channel 33a, which has a circular flow cross section, and in the connection channels 33b, which are also circular-cylindrical. The volume regions with high turbulence lead to flow-induced vibrations. This is attributable, inter alia, to the alignment of the connection channels 33b and the inlet channel 33a at an angle of 90° with respect to one another, which leads to flow separation, and to the different diameters of the connection channels 33b and of the inlet channel 33a. In the configuration of the fluid distributor 33 shown in FIG. 3, design guidelines for low-turbulence flow guidance are infringed on account of installation space limitations.

It was found that even the constant flow cross section of the circular-cylindrical inlet channel 33a is unfavorable with respect to the flow guidance: Owing to the fact that the volume flow in the inlet channel 33a decreases starting from the inlet opening 29 because some of the volume flow is removed from the inlet channel 33a at each connection channel 33b, there is a reduction in the flow velocity in the longitudinal direction (y-direction) of the inlet channel 33a. This may lead to flow separation, especially in the vicinity of the end of the inlet channel 33a distant from the inlet opening 29 and hence lead to turbulent and/or periodic fluctuation movements (exponential gradient of the flow velocity), as indicated in FIG. 3.

What follows is a description of how a cross-sectional adaptation or a reduction in the flow cross section A of the inlet channel 33a can homogenize the velocity or pressure gradient of the fluid 28 in the inlet channel 33a in order to prevent separation of the fluid 28.

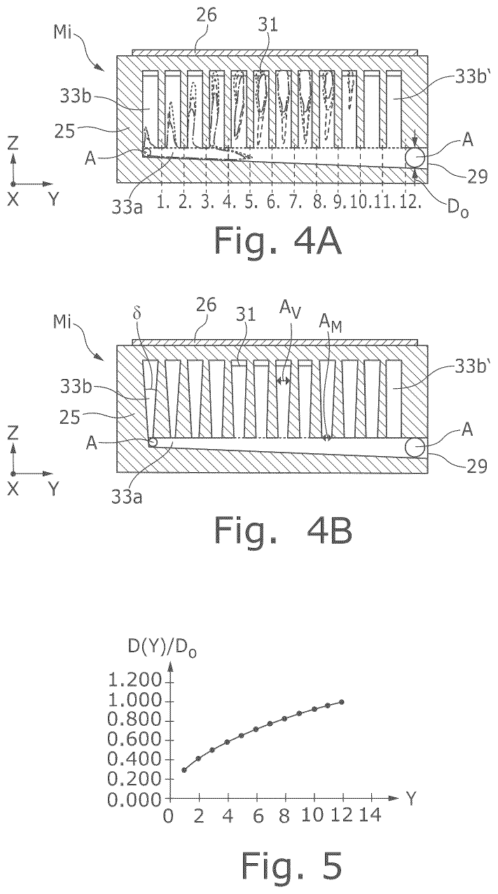

In the example shown in FIGS. 4A-4B, the inlet channel 33a has a flow cross section A which decreases in the longitudinal direction y of the inlet channel 33a starting from a connection channel 33b′ adjacent to the inlet opening 29. To make matters clear, the local, circular flow cross section A in the region of the connection channel 33b′ adjacent to the inlet opening 29 and at the end of the inlet channel 33a distant from the inlet opening 29 are illustrated in FIGS. 4A-4B. It is understood that the circular flow cross section A of the inlet channel 33a runs in the xz-plane perpendicular to the longitudinal direction y of the inlet channel 33a, contrary to the illustration in FIGS. 4A-4B.

In the example shown in FIGS. 4A-4B, the flow cross section A decreases linearly in the longitudinal direction y of the inlet channel 33a, and this was found to be favorable for the reduction of flow-induced vibrations as this results in a constant decrease in the velocity of the fluid 28 in the axial direction or a constant decrease in the pressure gradient. Since the flow cross section A is proportional to the square of the diameter D² or to the square of the radius R² (A˜R² or D²), a linear decrease in the flow cross section A in the longitudinal direction y of the inlet channel 33a involves the diameter D to be scaled with the root of the distance y from the maximum radius or diameter D₀ of the inlet channel, as depicted in FIG. 5, which shows the ratio D(y)/D₀ as a function of the y-coordinate, wherein the numerical values on the abscissa of the diagram shown in FIG. 5 correspond to the twelve positions in the longitudinal direction (y-direction) of the inlet channel 33a shown in FIG. 4A. The curve shown in FIG. 5 can be described analytically by the following equation: D(y)/D₀=0.2887×y^{0.5}.

Unlike what is shown in FIGS. 4A-4B, the profile shown in FIG. 5 might optionally be approximated by virtue of linearly approximated sections being inserted between the twelve positions depicted in FIG. 4A, i.e. two of the numerical values shown in FIG. 5 are connected by a straight line in each case. Such an approximated linear profile may be desirable from a manufacturing point of view.

In a manner analogous to the illustration of FIG. 3, FIG. 4A shows the turbulent kinetic energy of the fluid 28 in the fluid distributor 33. On the basis of a comparison between FIG. 4A and FIG. 3, it is evident that the turbulent kinetic energy in the inlet channel 33a in FIG. 4A is significantly reduced in comparison with that in the inlet channel 33a in FIG. 3. If this effect is quantified with regard to the effects on flow-induced vibrations, it turns out that a reduction of approx. 30-90% is possible. A further reduction in the flow-induced vibrations can be achieved by a further iterative optimization of the profile of the flow cross section A in the longitudinal direction y of the inlet channel 33a.

As also evident from FIG. 4A, the flow cross section A of the inlet channel 33a decreases with increasing distance from the inlet opening 29, while the diameter or the flow cross section of the connection channels 33b remains constant in the longitudinal direction y of the inlet channel 33a. This leads to a significant jump in cross section occurring at the transition to the respective connection channels 33b in the vicinity of the left-hand end of the inlet channel 33a in FIG. 4A. In order to counteract a local increase in the flow-induced vibrations on account of the jump in cross section, an opening cross section M of a respective connection channel 33b in the example shown in FIG. 4B decreases starting from the connection channel 33b′ adjacent to the inlet opening 29. The connection channels 33b have an (averaged) flow cross section A_{V} that decreases with increasing distance from the cooling channels 31.

In the example shown in FIG. 4B, the connection channels 33b are of conical form and each have an opening angle δ which is less than 8°. The opening cross section A_{M} of a respective connection channel 33b was chosen in such a way here that, where possible, there is no jump in cross section at the transition between the inlet channel 33a and the respective connection channel 33b, i.e. the opening cross section A_{M} is determined by the local diameter D(y) of the inlet channel 33a.

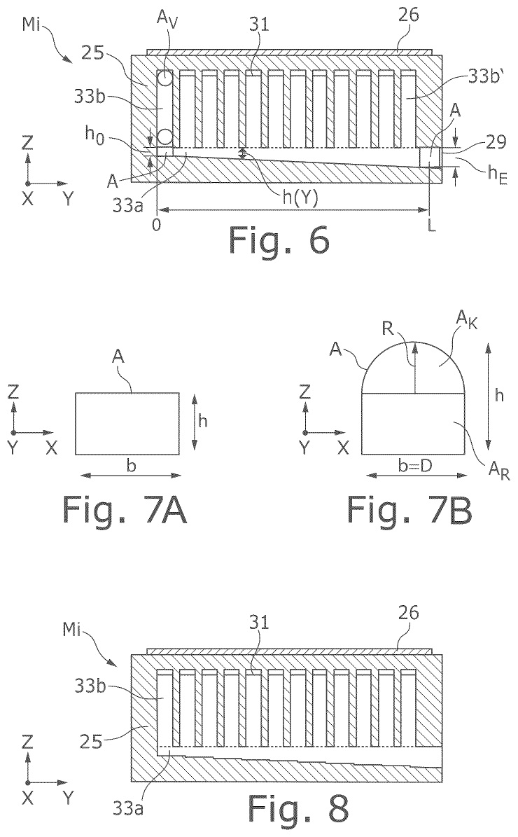

FIG. 6 shows a further option for generating a linear decrease in the flow cross section A in the longitudinal direction y of the inlet channel 33a. In the example shown in FIG. 6, the flow cross section A is rectangular and has a height h extending in the vertical direction (z-direction) as well as a width b which extends transversely to the plane (yz-plane) in which the connection channels 33b and the inlet channel 33a are located (cf. also FIG. 7A). As indicated in FIG. 6, the width b of the rectangular flow cross section A is constant in the longitudinal direction y of the inlet channel 33a, but the height h of the rectangular flow cross section A decreases linearly starting from the connection channel 33b′ adjacent to the inlet opening 29. Accordingly, the flow cross section A also decreases linearly in the longitudinal direction y of the inlet channel 33a since it is proportional to the height (A˜h). The relationship between the height h(y) and the y-coordinate in the longitudinal direction y of the inlet channel 33a, the zero point of which has been set (arbitrarily) at the end of the inlet channel 33a distant from the inlet opening 29, emerges as follows in the example shown in FIG. 6:

$$h ( y ) = {h}_{0} + y / L ( {h}_{E} - {h}_{0} ) ,$$

where h₀ denotes the minimum height, h_{E} denotes the maximum height and L denotes the length of the inlet channel 33a, along which the flow cross section A decreases linearly. The constant width b of the flow cross section A eliminates the problem, described in connection with FIGS. 4A-4B, of a jump in cross section at the transition between the inlet channel 33a and the connection channels 33b. In the example shown in FIG. 6, the connection channels 33b therefore have a constant, circular flow cross section A_{V}, as indicated in FIG. 6.

It is understood that the inlet channel 33a need not have a flow cross section A that decreases over the entire length thereof; rather, the flow cross section may for example be constant in the section of the inlet channel 33a which is arranged adjacent to the inlet opening 29 and in which no connection channels 33b open into the inlet channel 33a. For example, this may be desirable for connecting the inlet channel 33a with a fluid port.

In place of the rectangular flow cross section A shown in FIG. 7A, the inlet channel 33a may have a flow cross section A as shown in FIG. 7B and composed of a rectangular cross-sectional portion A_{R} and a semicircular cross-sectional portion AK. In the case of the flow cross section A shown in FIG. 7B, too, the width b of the rectangular cross-sectional portion A_{R} is constant and the height h thereof decreases linearly in the longitudinal direction y of the inlet channel 33a. It is understood that the inlet channel 33 may also have flow cross sections A with different geometries to the ones shown in FIGS. 4A-4B and FIGS. 7A-7B.

It is not mandatory for the flow cross section A of the inlet channel 33a to decrease continuously (linearly). Instead, it is also possible for the flow cross section A to decrease in steps or in a stepwise (cascaded) manner, as illustrated in FIG. 8 for the rectangular flow cross section A shown in FIG. 6. The greater the number of steps, the generally smaller the change in the flow cross section A at the respective step. Changes in the flow cross section that are too large (>5% in relation to the respective larger flow cross section at the step) should be avoided in order to prevent local flow separations. In FIG. 8, the flow cross section A is reduced in comparatively large steps for illustration purposes.

As an alternative to the rectangular flow cross section A shown in FIG. 8, the flow cross section A decreasing in a stepwise manner may have a different geometry. The stepwise decrease in the flow cross section A enables the manufacture of the inlet channel 33a with the aid of conventional production methods, albeit with greater outlay. What applies in general is that the above-described designs of the fluid distributor 33 are typically produced with the aid of alternative or novel manufacturing methods, for example with the aid of selective laser etching or with rear-side laser ablation.

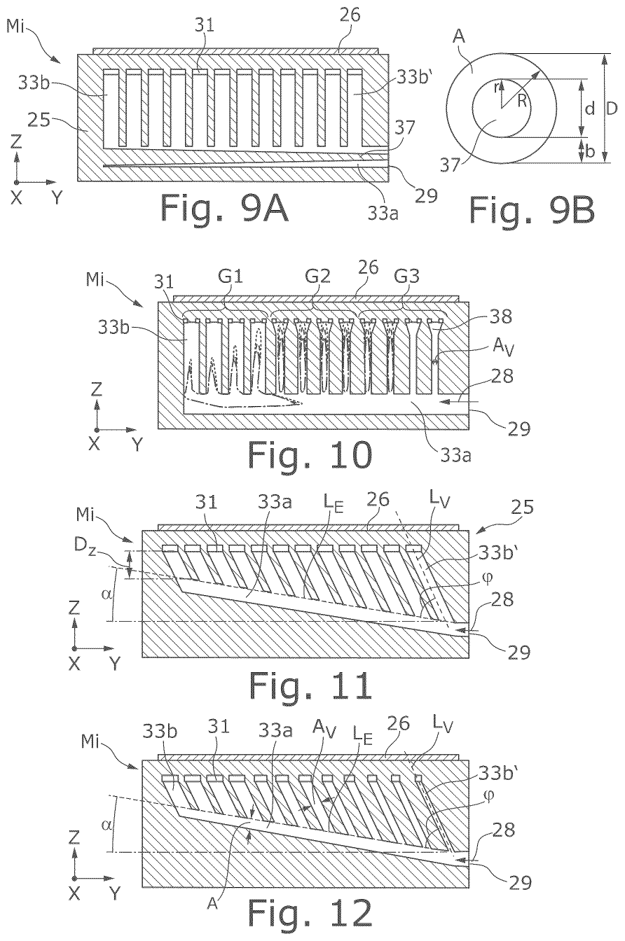

In the case of the mirror Mi shown in FIG. 9A, the inlet channel 33a has a ring-shaped flow cross section A, which is illustrated in FIG. 9B. To generate the ring-shaped flow cross section A, material in the form of a ring is removed from the main body 25 of the mirror Mi, with a conical frustum 37 with a circular cross-sectional area being formed, the radius r of which increases with increasing distance from the inlet opening 29, as evident from FIG. 9A. The outer radius R or the outer diameter D of the ring-shaped flow cross section A of the inlet channel 33a formed in this way is constant. This gives rise to a circular ring-shaped gap with a flow cross section A that decreases starting from the inlet opening 29 or from the connection channel 33b′ adjacent to the inlet opening 29. In the example shown in FIGS. 9A-9B, the following applies to the ring-shaped flow cross section A:

$$A = π ( {R}^{2} - {r}^{2} ) = π ( d + b ) b = π ( D - b ) b ,$$

where b and hence also the flow cross section A are dependent on the y-coordinate or the longitudinal direction of the inlet channel 33a. In the example shown in FIGS. 9A-9B, too, there may be a linear decrease of the flow cross section A in the longitudinal direction of the inlet channel 33a if the width b(y) is suitably chosen.

It is understood that the ring-shaped flow cross section A need not necessarily be annular but may have another geometry, e.g. an elliptical, rectangular, oval or free-form geometry. In an alternative to the example shown in FIGS. 9A-9B, the conical frustum 37 might not be part of the main body 25 but rather be an additional component which is introduced into the inlet channel 33a, which is cylindrical in this case, via the inlet opening 29 and suitably secured. The additional component, which is rod-shaped in this case, may for example be attached to a fluid line which is fastened to the inlet opening 29 and secured there.

FIG. 10 shows a mirror Mi in which the inlet channel 33a has a constant flow cross section A, in contrast with the examples described above. In the example shown in FIG. 10, the connection channels 33b have different flow cross sections A_{V}. As a result of the different flow cross section A_{V} of the connection channels 33b, it is possible to influence the counterpressure or the volume flow discharge from the inlet channel 33a in order to generate a pressure gradient that is as constant as possible in the inlet channel 33a. In order to achieve this, the flow cross section A_{V} of each individual connection channel 33b may be defined individually. It was found that an increase in the flow cross section A_{V} of the connection channels 33b starting from the connection channel 33b adjacent to the inlet opening 29 is favorable for the reduction of flow-induced vibrations.

In the example shown in FIG. 10, this is realized by virtue of the fact that three groups G1, G2, G3 of connection channels 33b are present, with the flow cross section A_{V} being the same in each group. The flow cross section A_{V} of the third group G3, which is arranged adjacent to the inlet opening 29, is smaller in this case than the flow cross section A_{V} of the second group G2, and the flow cross section Ay of the second group G2 is smaller than the flow cross section A_{V} of the first group G1 of connection channels 33b.

The turbulent kinetic energy within the fluid distributor 33, which is significantly reduced (by approx. 10%-50%) in comparison with the conventional fluid distributor 33 shown in FIG. 3, is also evident in FIG. 10. The example shown in FIG. 10 may serve as a starting point for an iterative optimization of the flow guidance in the fluid distributor 33, within the scope of which the flow cross section A_{V} is defined individually in the respective connection channels 33b. It is understood that a different division of the connection channels 33b into groups is also possible; for example, it is possible to form four groups, each with three connection channels 33b that each have the same flow cross section A_{V}.

As likewise evident from FIG. 10, the connection channels 33b of the second and third groups G2, G3 each have a conical section 38 at the transition to the cooling channels 31. The conical section 38 serves to prevent a jump in cross section at the transition between the respective connection channel 33b and the cooling channels 31. As evident from FIG. 10, each of the connection channels 33b is connected to two adjacent cooling channels 31, to which the fluid 28 is supplied. A jump in cross section at the transition to the cooling channels 31 can be avoided on account of the conical section 38 of the connection channels 33b of the second and third groups G2, G3, which each have a flow cross section A_{V} that is smaller than the distance in the y-direction between two adjacent cooling channels 31. It is understood that there may be a deviation in terms of arrangement and configuration of the conical sections 38 from the configuration shown in FIG. 10.

In the examples described above, the connection channels 33b are aligned in the vertical direction (z-direction) and the inlet channel 33a runs in the horizontal direction (y-direction), leading to a 90° deflection of the fluid 28 at the opening of the connection channels 33b, and this may result in a flow separation that may cause flow-induced vibrations. In order to reduce the flow-induced vibrations, an acute outflow angle φ of less than approx. 70° between a longitudinal direction L_{V} of the connection channels 33b and a longitudinal direction L_{E} of the inlet channel 33a is chosen in the example of FIG. 11. In order to generate an outflow angle φ that is as small as possible, a respective connection channel 33b is aligned at an angle to the z-direction in the example shown in FIG. 11, and the inlet channel 33a is also aligned at an angle α to a horizontal plane (xy-plane). In the example shown in FIG. 11, a distance D_{Z} in the z-direction between the cooling channels 31 and the inlet channel 33a accordingly decreases starting from the connection channel 33b′ adjacent to the inlet opening 29. Unlike what is illustrated in FIG. 11, the longitudinal direction L_{E} of the inlet channel 33a being inclined with respect to the horizontal or the longitudinal direction L_{V} of the connection channels 33b being inclined with respect to the z-direction is sufficient for the generation of an acute outflow angle φ.

FIG. 12 shows a mirror Mi in which the three measures described above, i.e. the decrease in the flow cross section A in the inlet channel 33a as described in the context of FIGS. 4A-4B, FIG. 6 and FIG. 8, the increase in the flow cross section A_{V} in the connection channels 33b as described in the context of FIG. 10 and the use of an acute outflow angle q as described in the context of FIG. 11, are combined with one another. In the design of the fluid distributor 33 shown in FIG. 12, it is desirable to be mindful of a possibly arising interaction between the individual measures.

In the above-described hollow structure 27, the assumption was made that the fluid distributor 33 and the fluid collector 34 have an identical geometry, i.e. that the statements made above in respect of the fluid distributor 33 also apply analogously to the fluid collector 34. However, it is possible in principle for the fluid distributor 33 and the fluid collector 34 to have different geometries since a different dimensioning to the dimensioning of the fluid distributor 33 may optionally be more desirable for the fluid collector 34.

The component whose main body 25 comprises the hollow structure 27 need not necessarily be an optical element in the form of a mirror Mi. It may also be a different optical element or a non-optical component, for example a structural component of the projection exposure apparatus 1. The component comprising the main body 25 with the flow-optimized hollow structure 27 may also be used in a different optical arrangement to the projection exposure apparatus 1 described above, for example in a lithography apparatus designed for the DUV/VUV wavelength range.

In general, it holds true that the flow guidance may also be improved by rounding off sharp edges, etc. of the hollow structure 27, whereby flow-induced vibrations are reduced. The introduction of radii in place of sharp, angled transitions within the hollow structure 27 also has an desirable effect on the reduction of flow-induced vibrations.

What is claimed is:

1. A component, comprising:
a main body comprising a hollow structure, the hollow structure comprising channels through which a fluid is flowable, the hollow structure further comprising a fluid distributor and a fluid collector,
wherein:
the fluid distributor comprises connection channels opening into a common inlet channel connected to an inlet opening, and/or the fluid collector comprises connection channels opening into a common outlet channel connected to an outlet opening; and
the inlet channel has a flow cross section that decreases starting from a connection channel adjacent to the inlet opening; and/or the outlet channel has a flow cross section that decreases starting from a connection channel adjacent to the outlet opening.

2. The component of claim 1, wherein the flow cross section of the inlet channel decreases linearly in a longitudinal direction, and/or wherein the flow cross section of the outlet channel decreases linearly in a longitudinal direction.

3. The component of claim 1, wherein the inlet channel has a circular flow cross section, and/or the outlet channel has a circular flow cross section.

4. The component of claim 1, wherein the inlet channel has a rectangular flow cross section or a rectangular cross-sectional portion, and/or the outlet channel has a rectangular flow cross section or a rectangular cross-sectional portion.

5. The component of claim 1, wherein the inlet channel has a flow cross section comprising a rectangular cross-sectional portion and a semicircular cross-sectional portion, and/or the outlet channel has a flow cross section comprising a rectangular cross-sectional portion and a semicircular cross-sectional portion.

6. The component of claim 1, wherein the inlet channel has a ring-shaped flow cross section, and/or the outlet channel has a ring-shaped flow cross section.

7. The component of claim 1, wherein an opening cross section of a connection channel of the fluid distributor decreases starting from a connection channel adjacent to the inlet opening, and/or an opening cross section of a connection channel of the fluid collector decreases starting from a connection channel adjacent to the outlet opening.

8. The component of claim 1, wherein a connection channel has a flow cross section that decreases with increasing distance from the cooling channels.

9. The component of claim 8, wherein the connection channel is conical.

10. The component of claim 1, wherein the flow cross section of the inlet channel decreases in steps, and/or the flow cross section of the outlet channel decreases in steps.

11. The component of claim 1, wherein a flow cross section of the connection channels increases starting from a connection channel adjacent to the inlet opening, or the flow cross section of the connection channel increases starting from a connection channel adjacent to the outlet opening.

12. The component of claim 1, wherein the flow cross sections of two adjacent connection channels have the same size.

13. The component of claim 1, wherein at least one connection channel has a conical section at a transition to the cooling channels.

14. The component of claim 1, wherein a longitudinal direction of the connection channels and a longitudinal direction of the inlet channel are oriented at an acute outflow angle relative to each other, and/or a longitudinal direction of the connection channels and a longitudinal direction of the outlet channel are oriented at an acute outflow angle relative to each other.

15. The component of claim 1, wherein a distance between the inlet channel and the cooling channels decreases starting from a connection channel adjacent to the inlet opening, and/or a distance between the outlet channel and the cooling channels decreases starting from a cooling channel adjacent to the outlet opening.

16. The component of claim 1, wherein the main body comprises first and second partial bodies rigidly connected to each other along a joining surface, and the hollow structure is in at least the first partial body.

17. An optical arrangement, comprising:
a component according to claim 1; and
a cooling device configured to flow the cooling fluid through the hollow structure.

18. The optical arrangement of claim 17, wherein the optical arrangement comprises a lithography system.

19. A component, comprising:
a main body comprising a hollow structure, the hollow structure comprising channels through which a fluid is flowable, the hollow structure further comprising a fluid distributor and a fluid collector,
wherein:
the fluid distributor comprises connection channels opening into a common inlet channel connected to an inlet opening, and/or the fluid collector comprises connection channels opening into a common outlet channel connected to an outlet opening;
the inlet channel has a constant flow cross section, and/or the outlet channel has a constant flow cross section; and
at least two of the connection channels have different flow cross sections.

20. An optical arrangement, comprising:
a component according to claim 19; and
a cooling device configured to flow the cooling fluid through the hollow structure.
